(19) United States
(12) Patent Application Publication
(10) Pub. No.: US 2025/0122074 A1
(43) Pub. Date: Apr. 17, 2025

(54) MOUNTING DEVICE FOR A HOUSING, AND PRODUCTION METHOD

(71) Applicant: Robert Bosch GmbH, Stuttgart (DE)

(72) Inventors: Andreas Menzel, Reutlingen (DE); Bora Ersoez, Leinfelden-Echterdingen (DE); David Thissen, Tuebingen (DE); Joachim Kreutzer, Stuttgart (DE); Lucas Middelburg, Pfronstetten (DE)

(21) Appl. No.: 18/688,732

(22) PCT Filed: Jan. 25, 2023
(86) PCT No.: PCT/EP2023/051727

§ 371 Date: Mar. 1, 2024

(30) Foreign Application Priority Data
Feb. 3, 2022 (DE) 10 2022 201 160.0

(51) Int. Cl. B81C 99/00; G01D 11/24; G01D 11/30

(52) U.S. Cl. CPC B81C 99/002; G01D 11/245; G01D 11/30

(57) ABSTRACT

A mounting device for a micromechanical structural element, such as a sensor element. The mounting device includes at least one flexible carrier element, the structural element, and a stiffening element. The structural element is applied to a first side of the flexible carrier element in a first region, the stiffening element is provided on the opposite second side of the carrier element in a second region, and the flexible carrier element can be electrically connected, as a result of which compact and flexible installation of the sensor structure is made possible.

### FIELD

The present invention relates to a mounting device for a structural element, which can be mounted in a housing, and to a production method for the mounting device.

### BACKGROUND INFORMATION

For system-related reasons, environmental sensors, such as pressure sensors or gas sensors, require access to the surroundings in order to be able to detect corresponding sensor variables. For this purpose, it must be ensured that the sensor element contained in the sensor can interact with the surroundings, e.g., via an access channel through which a medium can be guided to the sensor element. Both when using separate environmental sensors as individual structural components and when integrating them into higher-level evaluation and/or control devices, it is necessary that certain parts of the sensor or of the evaluation/control devices that are necessary for operation are not influenced by the surroundings. Suitable positioning of the sensor element in the structure of an individual sensor or within an evaluation/control device must therefore be suitably designed both with regard to the supply of the ambient medium and with regard to the seal to the interior.

In particular in the case of micromechanical sensors (MEMS), the production usually takes place by applying a sensor element to a rigid substrate in order to obtain a base for the further sensor components and to prevent undesired warping during the later mounting of the structure into a higher-level system. In addition, seals or passivations for the sensor are provided in order to prevent ingress of the ambient medium into regions that are not provided for detecting the sensor variable. Seals, such as sealing rings or other sealing materials, can also be used to fix and lock the sensor or, in general, the sensor element in the housing in order, for example, to fix the orientation toward an access channel.

Since the sensor is usually used in a higher-level context, e.g., a housing or a higher-level evaluation and/or control device, it is frequently connected by means of a rigid or flexible printed circuit board. A flexible printed circuit board in particular offers the advantage of being able to position the sensor relatively freely in the higher-level system and of simultaneously enabling an electrical connection to further electronic components and an energy supply.

However, the use of a rigid substrate has the disadvantage that the mounting and the contacting necessary in the process can, in some circumstances, lead to limitations in positioning within a higher-level system, such as an evaluation and/or control device. In particular, the connection of the rigid substrate of the sensor to a rigid or flexible printed circuit board as a connection to the higher-level context can lead to a high overall height of the sensor to be integrated, which limits or even prevents integration into significantly miniaturized applications.

### SUMMARY

The present invention provides a structure of a sensor in the form of a mounting device that enables a more flexible and/or more compact arrangement or positioning in a higher-level system.

In order to achieve a more flexible use of a sensor structure, a mounting device for an in particular micromechanical structural element, such as a sensor element, is provided in accordance with the present invention. According to an example embodiment of the present invention, in this case, the mounting device comprises at least one flexible carrier element, the structural element, and a stiffening element. The structural element is applied, e.g., soldered and/or glued, to a first side of the flexible carrier element in a first region, and the stiffening element is applied to the opposite second side of the carrier element in a second region.

By such an arrangement of the, for example sensitive, structural element on the one side and of the stiffening element on the opposite second side of the carrier element, it can be achieved that only the region of the carrier that serves as the basis of the sensitive structural element is designed to be rigid, whereas the region of the carrier element that extends beyond the former remains flexible and adaptable. A flexible printed circuit board, e.g., a flex PCB or, in general, a film, on which conductor traces can be applied or integrated for contacting purposes, can be used as the flexible carrier element. Such films on the basis of, for example, polyimide or the like have already been used for a long time in integrated circuit packaging. The use of films as a carrier element also has the advantage that the structure can be designed to be flatter in comparison to the use of a semiconductor substrate or a PCB substrate as a carrier element. This is made possible in particular in that the combination of a flexible carrier element for contacting and a, preferably metal, stiffening element for stabilization can enable a flatter structure than a rigid substrate, for example made of organic material, having the same overall stiffness.

In a development of the present invention, the structural element or the sensor element can be at least partially enclosed on the first side by a further structural component. This structural component can also be fixedly connected to the flexible carrier element in the first region or adjacent to the first region. This structural component preferably has an opening in the sense of an access channel, through which an ambient medium can be guided to the structural element or the sensor element. In order to protect the structural component from damaging substances of the ambient medium, a passivation medium, e.g., a gel, can be introduced into the opening. The passivation medium can partially or completely cover the structural component. In the case of a sensor element, it can thus be provided that at least one detection means and/or the contacting means are covered in order to prevent measurement value distortion and/or corrosion. Alternatively or additionally, an in particular porous membrane, introduced onto or into the structural component, can be used to keep off damaging substances of the ambient medium.

According to an example embodiment of the present invention, the structural component, which at least partially encloses the structural element or the sensor element, can also be equipped with a receptacle, into which a sealing element is introduced or attached. In this case, both sealing rings and other sealing materials, which can, for example, be injected into the receptacle, are suitable. The sealing element is preferably designed to interact with a cover applied to the structural component, in order to prevent the ingress of the ambient medium outside the access channel defined by the opening. In particular, this prevents the ingress of the ambient medium into a higher-level system.

According to an example embodiment of the present inventon, the stiffening element on the second side of the carrier element can be generated directly on the carrier element or can be connected to the carrier element as a prefabricated element. In this case, the surface that is covered by the stiffening element can correspond to at least the corresponding surface that is covered by the structural element on the opposite first side. It can thus be achieved, for example, that at least the structural element is not exposed to any mechanical forces during mounting.

Furthermore, it can be provided that the stiffening element is constructed in such a way that it can also serve as electrical and/or magnetic shielding of the structural element. For this purpose, it can be provided that the stiffening element partially or completely consists of a metal or an alloy. Alternatively, the stiffening element can also consist of a ceramic material or an organic material such as a plastics material.

In order to generate a counterforce that acts, for example, on the sealing element or on a cover yet to be attached or on a covering in the higher-level system, the stiffening element can be equipped with a spring element. The spring element can be connected directly or indirectly to the stiffening element, i.e., as an integral part or as an additional element.

The mounting device according to the present invention is advantageously suitable for being arranged in a housing. For this purpose, according to an example embodiment of the present invention, the flexible carrier element can have electrical contactings, which allow for both the structural element and/or an external electrical connection. Advantageously, the housing also has a cover, by means of which the structural element and/or the structural component attached to the carrier element is fixed. Alternatively or additionally, the cover, in connection with a sealing element, can also generate a seal with respect to the ambient medium. Of course, a seal by the cover can also be achieved with the structural component or the structural element as such.

According to an example embodiment of the present invention, in order to generate the seal, it can be provided that the cover exerts a force on the sealing element, which force has a force component that is directed substantially perpendicularly onto the stiffening element. As a result, the force thus generated can be absorbed by the stiffening element.

Correspondingly, a second force component that is directed substantially perpendicularly onto the second side of the carrier element can be generated by means of the spring element. In this case, it can preferably be provided that this second force component presses the sealing element against the cover.

According to the present invention, a method is also provided in which the in particular micromechanical structural element, for example a sensor element, is generated or applied on the first side of the flexible carrier element and the stiffening element is generated or applied on the second side.

Further advantages can be seen from the following description of exemplary embodiments or from the rest of the disclosure herein.

### BRIEF DESCRIPTION OF THE DRAWINGS

FIGS. 1A and 1B show a first exemplary embodiment of the present invention.

FIGS. 2A and 2B show a second exemplary embodiment of the present invention.

FIG. 3 shows a modification of the second exemplary embodiment of the present invention.

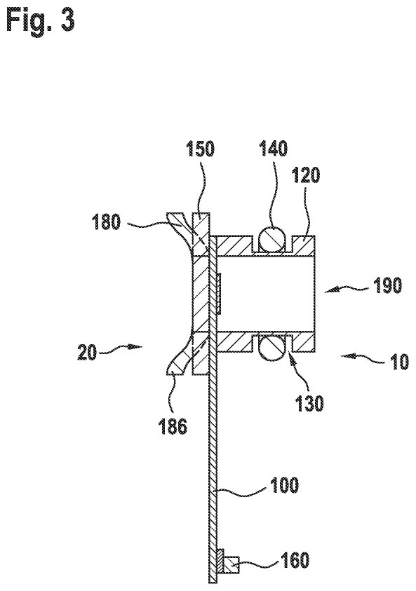

FIGS. 4A to 4D show possible designs of the seal used.

FIG. 5 shows a flow diagram of an example production method of the present invention.

### DETAILED DESCRIPTION OF EXAMPLE EMBODIMENTS

In order to install structural elements, such as micromechanical sensors or ASICs (application-specific integrated circuit, IC having predetermined functionality) into larger systems, such as evaluation devices, control devices, or application devices, they are often accommodated in housings by means of a (mold) cap. These housings are usually rigid, inflexible, and inelastic and contain wire legs for contacting, for example on a printed circuit board. However, many applications require a more flexible arrangement of the structural elements, so that such a rigid cap and contacting can be a hindrance.

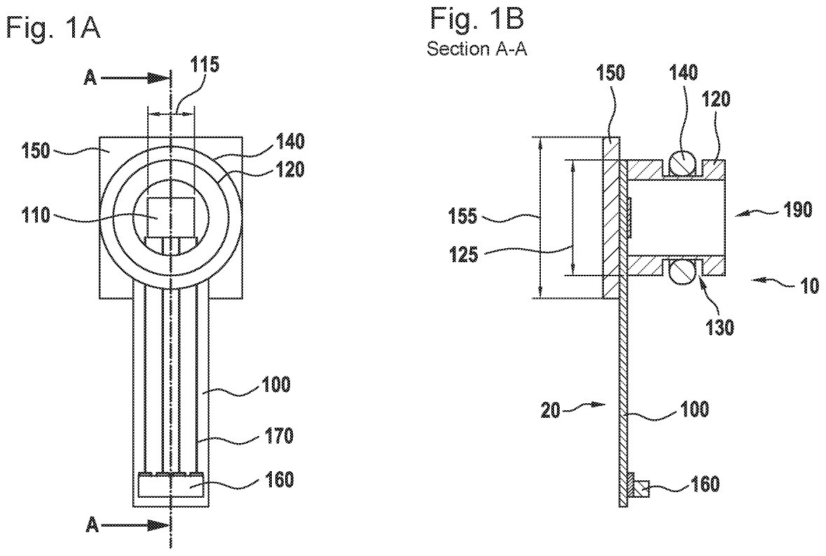

As shown with the first exemplary embodiment according to FIG. 1A and a cross-section or side view in FIG. 1B, the present invention describes a mounting device for a structural element that allows more freedom and possibilities with regard to positioning and contacting. Despite this more flexible positioning possibility, the mounting device has sufficient stabilization for the structural element so that no undesired mechanical interfering influences act on the structural element during mounting in a higher-level system or during use of the structural element.

A flexible carrier element 100 onto which the structural element 110 is applied in a first region 115 from a first side 10 is used as the basis for the flexible mounting device. The carrier element 100 can be a flexible film, e.g., a flex PCB film. Alternatively, however, the flexible film can also consist of other materials, such as polyimide. Electrical conductor traces 170 and a contacting 160 for an external electrical connection to the higher-level system or housing can be provided on the film 100. Alternatively, the electrical conductor traces 170 can also be integrated into the film. This would have the advantage that they are even better protected against damage, for example during mounting. In both cases, the contacting 160 can consist of a connection element located directly on the film 100 and a region located thereon for electrical and/or mechanical connection to an external device. For electrical contacting of the structural element 110 and/or the electrical energy supply thereof, further contactings can also be provided in the first region 115 or in the vicinity thereof. In order to prevent interfering influences on the structural element 110, for example due to mechanical stresses, it is furthermore provided that a stiffening element 150 is applied in a second region 155 from the second side 20 of the carrier element 100. In this case, the stiffening element 150 can be applied as a prefabricated element to the carrier element 100 or can be generated, e.g., deposited, directly on the surface of the carrier element 100.

This stiffening element 150 brings about a local stiffening of the flexible carrier element 100, in particular in the first region 115 in which the structural element 110 is applied or arranged. In order to protect the structural element 110, which can, for example, have a sensor element for detecting a pressure, against disturbing mechanical stresses during mounting or in operation, the surface of the second region 155, in which the stiffening element 150 is applied or arranged, can be greater than the surface of the first region 115. It is preferred here that the second region 155 extends beyond the first region 115.

In a development of the embodiment, a structural component 120 can additionally be provided, which is applied or arranged around the structural element 110 on the first side 10 of the carrier element 100. This structural component 120 at least partially encloses the structural element 110 and thus laterally protects it from any damage. The structural component 120 has an opening 190, which enables access by the ambient medium to the structural element 110. By means of the access channel designed in this way, it can, for example, be achieved that an ambient pressure can be guided to a pressure sensor element and/or the ambient atmosphere can be guided to a gas sensor element as the structural element 110. In order to also protect the arrangement or the fastening of the structural component 120 on the carrier element 100 against mechanical stresses, it can be provided that the first region 115 is expanded to the surface 125, i.e., to the surface 125 that the structural component 120 occupies on the carrier element 100. Here too, in order to avoid undesired coupling of mechanical stresses, it can be provided that the second region 155 is larger than the surface 125.

For passivation of the structural element 110 or of the sensor element used, a passivation medium, e.g., a gel, can be introduced into the opening 190. This passivation medium can cover the entire structural element 110 or also only a portion thereof, e.g., the sensing component and/or contacting elements.

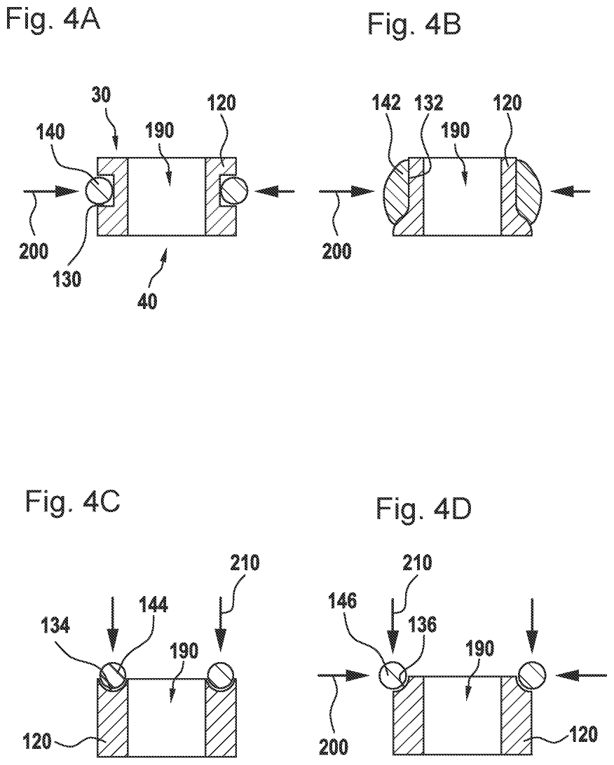

In order to seal and/or fix/lock the mounting device in a higher-level system, e.g., a housing or another application, a sealing element 140 can additionally be provided. As shown in FIG. 1B, this sealing element 140 can be designed as a sealing ring, which is introduced into a receptacle 130 provided for this purpose in the upper region of the structural component 120 that is remote from the carrier element 100. Alternatively, such a sealing element can also be provided in another design, as shown in FIGS. 4A to 4D. FIG. 4A corresponds to the structure of FIG. 1B, wherein the arrows indicate a possible force component that is exerted by an additional cover or a mating element of the housing on the sealing element 140 for sealing. In this example, a lateral force component 200, i.e., a force component parallel to the carrier element 100 but perpendicular to the opening 190, is generated and presses the sealing ring 140 into the receptacle 130. In the embodiment according to FIG. 4B, a sealing material 142 is applied in the upper region to a receptacle 132, which extends in particular around the opening 190. In this embodiment too, a lateral force component 200 can be generated by a further housing element such as a cover. According to the embodiment of FIG. 4C, a receptacle 134 can also be provided at the upper end 30 of the structural component 120, into which receptacle a sealing ring 144 or, in general, a sealing material can be applied. In this case, a perpendicular force component 210 that is directed in the direction of the carrier element 100 and thus onto the stiffening element 150 can be generated by a cover of the housing placed thereon. Such a seal enables the use of the stiffening element 150 as a mating element. In addition, such a force component 210 can also be used when the structural component 120 is applied to the carrier element 100 by pressing the lower part 40 of the structural component 120 with an adhesive or a solder onto the carrier element 100. The design of FIG. 4D shows a receptacle 136 for the sealing ring 146 or, in general, a sealing material, which receptacle is arranged at the edge in the upper region of the structural component 120. In this case, both a perpendicular force component 210 in the direction of the carrier element 100 and a lateral force component 200 perpendicular to the opening 190 can be required. By means of such a combined 2-point force application, an even better seal to the housing cover can be achieved.

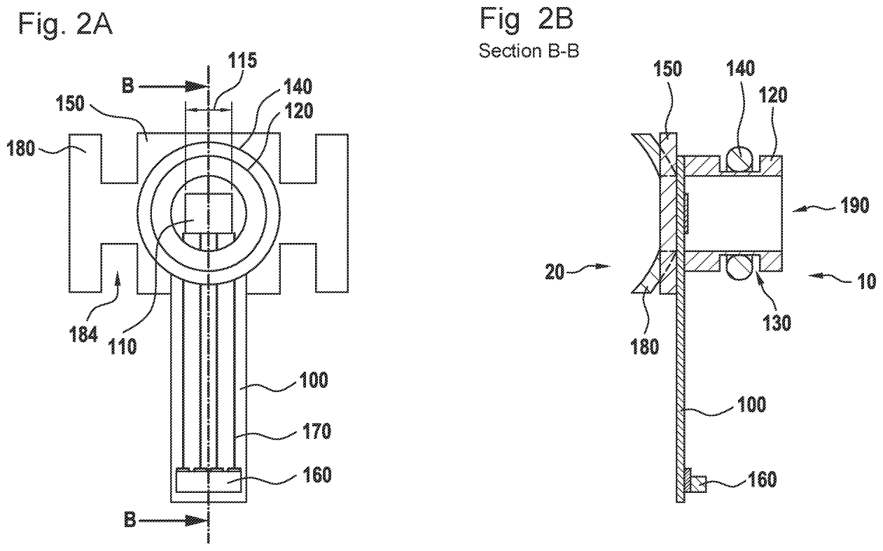

In a second exemplary embodiment according to FIG. 2A, it is provided that a spring element 180 is associated with the stiffening element 150, which spring element supports the sealing or fixing/locking of the mounting device in the higher-level system, e.g., a housing. The spring element 180 can thus be provided laterally in the form of a one-piece or multi-piece extension on the stiffening element 150. In this case, recesses 184 can be provided between the stiffening element 150 and the spring element 180, as shown in FIG. 2A. As can be seen in the cross-section of FIG. 2A in FIG. 2B, only the spring element 180 attached laterally to the stiffening element 150 generates the spring effect when the mounting device is applied with the second side 20 to a substrate. Alternatively or additionally, it can however also be provided that the stiffening element 150 is designed to be curved in the second region 155. The counterforce thus generated by the spring element 180 can additionally act on the sealing material and thus press the mounting device against the cover.

In order to mount the curved spring element 180, it can additionally be provided that the outer ends 186 are designed to be parallel to the stiffening element 150 or to the carrier element 100. As a result, the mounting device can be applied more simply to a flat surface and damages to the surface by edges of the stiffening element 150 or of the spring element 180 can be prevented.

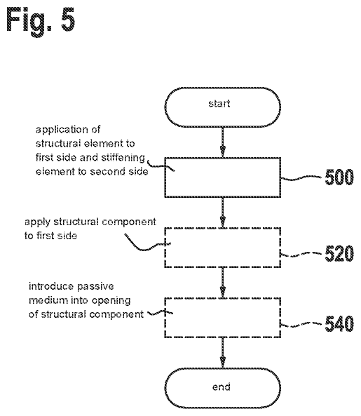

FIG. 5 describes a production method of the mounting device according to the present invention with reference to a flow diagram. Step 500 represents a combination of the application of the structural element 110 to the first side 10 of the carrier element 100 and of the stiffening element 150 to the second side 20 of the carrier element 100. In this case, the stiffening element 150 can be pre-produced and can be applied as a whole to the carrier element 100 or deposited directly on the surface.

In an optional step 520, the structural component 120 is applied to the first side 10 of the carrier element 100 in such a way that it at least partially encloses the structural element 110. Common methods are gluing, soldering, or otherwise connecting. Furthermore, in a subsequent optional method step 540, a passivation medium can be introduced into the opening 190 of the structural component 120, which passivation medium covers at least a portion of the structural component, and/or the opening 190 can be closed with a membrane that allows the relevant ambient properties, e.g., air pressure, to pass through but keeps off undesired ambient components, such as damaging substances.

1-14. (canceled)

15. A mounting device for a microelectromechanical structural element and ASIC for integration into a higher-level system, wherein the mounting device comprises:
a flexible carrier element;
the micromechanical structural element; and
a stiffening element;
wherein the structural element is applied to a first side of the flexible carrier element in a first region, and the stiffening element is provided at least in a second region located on an opposite second side of the flexible carrier element.

16. The mounting device according to claim 15, further comprising a structural component, which is applied to the first side of the carrier element in the first region and at least partially encloses the structural element.

17. The mounting device according to claim 16, wherein the structural element has a micromechanical sensor element, and wherein the structural component has an opening as an access for surroundings to the sensor element.

18. The mounting device according to claim 17, wherein a passivation medium is introduced around the sensor element and/or in the opening of the structural component, and at least partially covers the sensor element.

19. The mounting device according to claim 16, wherein the structural component has a receptacle for a sealing element.

20. The mounting device according to claim 15, wherein the stiffening element brings about an electrical and/or magnetic shielding of the structural element, wherein the stiffening element is at least partially metal.

21. The mounting device according to claim 15, wherein the stiffening element in the second region covers at least a surface of the first region.

22. The mounting device according to claim 15, further comprising a spring element in or on the second region, wherein the spring element is part of the stiffening element.

23. A housing for a micromechanical structural element including a microelectromechanical sensor element, comprising:
a mounting device, including:
a flexible carrier element,
the micromechanical structural element, and
a stiffening element,
wherein the structural element is applied to a first side of the flexible carrier element in a first region, and the stiffening element is provided at least in a second region located on an opposite second side of the flexible carrier element, and
wherein the structural component has a receptacle for a sealing element;
wherein the mounting device is attached with the second side of the carrier element in the housing, and the housing has a cover or a covering, which, for fixing and/or sealing, at least partially presses against the structural element and/or the structural component and/or the sealing element.

24. The housing according to claim 23, wherein the receptacle is arranged on the structural component in such a way that a first force component of the cover onto the sealing element is directed substantially perpendicularly onto the stiffening element.

25. The housing according to claim 24, wherein the spring element generates a second force component, which is directed substantially perpendicularly onto the carrier element from the second side, wherein the second force component presses the sealing element against the cover.

26. A method for producing a mounting device for a micromechanical structural element, the method comprising the following steps:
applying the micromechanical structural element to a first side of a flexible carrier element in a first region; and
applying or generating a stiffening element at least in a second region located on an opposite second side of the flexible carrier element.

27. The method according to claim 26, wherein the structural element has a sensor element, wherein a structural component is applied to the first side of the carrier element in the first region, the structural component at least partially enclosing the structural element, and wherein the structural component has an opening into which a passivation medium is introduced, which at least partially covers the sensor element.

28. The method according to claim 27, wherein the structural component has a receptacle into which a sealing element is introduced.
